(19) United States
(12) Patent Application Publication
(10) Pub. No.: US 2026/0276722 A2
(43) Pub. Date: Sep. 17, 2026

(54) FREQUENCY DOMAIN MONITORING OF STATE OF BATTERIES VIA A PIEZOELECTRIC ELEMENT

(71) Applicants: CALIFORNIA INSTITUTE OF TECHNOLOGY, Pasadena, CA (US); THE REGENTS OF THE UNIVERSITY OF CALIFORNIA, Oakland, CA (US)

(72) Inventors: Stewart Sherrit, Montrose, CA (US); Erik J Brandon, Pasadena, CA (US); Charles Soulen, Baden (CH); Ping Liu, San Diego, CA (US)

(21) Appl. No.: 19/358,310

(22) Filed: Oct. 14, 2025

Related U.S. Application Data
(60) Provisional application No. 63/708,389, filed on Oct. 17, 2024.

(51) Int. Cl. G01R 31/389; G01N 29/11; G01N 29/12; G01N 29/34; G01R 31/382; G01R 31/392

(52) U.S. Cl. CPC G01R 31/389; G01N 29/11; G01N 29/12; G01N 29/348; G01R 31/382; G01R 31/392; G01N 2291/025

(57) ABSTRACT

Systems and methods for implementing frequency domain techniques to determine acoustic changes in a battery via a piezoelectric element. In one aspect, a one-port piezoelectric network is formed by acoustically coupling a piezoelectric element to a battery. Impedance spectra of the one-port piezoelectric network are measured and correlated with the SoC and SoH of the battery. In another aspect, a two-port piezoelectric network is formed by acoustically coupling two piezoelectric elements to a battery. Ratio of voltages at the two piezoelectric elements of the two-port piezoelectric network are measured at different frequencies to generate voltage ratio spectra that are correlated with the SoC and SoH of the battery. Peaks in the impedance and voltage ratio spectra represent resonant modes of the battery that shift in frequency and/or amplitude based on the SoC and/or SoH of the battery. Reversible shifts correspond to the SoC and irreversible shifts to the SoH.

### CROSS REFERENCE TO RELATED APPLICATIONS

The present application claims priority to and the benefit of co-pending U.S. provisional patent application Ser. No. 63/708,389 entitled “State of Charge VIa a PiEzoelectric Resonator (SOCVIPER)”, filed on Oct. 17, 2024, the disclosure of which is incorporated herein by reference in its entirety.

### STATEMENT OF GOVERNMENT GRANT

This invention was made with government support under Grant No. 80NM0018D0004 awarded by NASA (JPL). The government has certain rights in the invention.

### TECHNICAL FIELD

The present disclosure relates to systems and methods for monitoring state of charge (SoC) and state of health (SoH) of electrochemical battery cells via a piezoelectric element configured to excite resonant frequency modes of the batteries.

### BACKGROUND

Use of electrochemical battery cells (batteries) has become ubiquitous with applications in nearly every aspect of day-to-day life including cars, homes, electronics goods and in more exotic applications such as space exploration. There is a desire to accurately determine the state of charge (SoC) of batteries, including rechargeable (e.g., secondary) batteries, to allow for better power management, including for improved prediction of available energy and operational time in applications such as electric vehicle, uncrewed aerial vehicles, and spacecrafts. In current applications, an estimation of the SoC may be made via integration of the delivered charge (i.e., coulomb counting) and knowledge of voltage-capacity curves (where there is a significant change in voltage vs. SoC) to errors up to 5% or higher (e.g., Ref. [1]). Knowledge of SoC may be important for flight missions using non-rechargeable (e.g., primary) batteries where no provision for re-charge is provided and therefore the stored capacity must be used cautiously. This becomes even more important as spacecraft become more autonomous, with less input from ground support.

During the charging and discharging cycles in a rechargeable battery and the discharging cycle in a non-rechargeable battery, both charge and mass transfer occur at the anodes and cathodes of the battery. This movement of ions creates local changes in the density, elasticity, and acoustic velocity that change the batteries acoustic properties. Furthermore, there are irreversible changes that are induced with the cell materials during the course of battery cycling, which manifests as mechanical changes in the battery materials (in particular the electrodes and electrolyte). These changes correspond to loss of useable capacity and is related to the SoH of the battery. Recent advances in external (to the battery) techniques such as acoustic time of flight (ToF) using ultrasonic pulses (e.g., Refs. [2] and [3]) have shown measurable and reproducible changes in the ToF with changes in the SoC which indicate acoustic changes internal to the battery. By measuring the shift in the time of flight, such time-domain technique can therefore be used to track mass movements and mechanical changes within the battery. The addition of the acoustic time of flight measurement is estimated to reduce the estimation error on the SoC of the battery to about one percent by combining the voltage charge curves, machine learning and acoustic changes in the battery during the charging and discharging cycles. However, measurement of ToF requires sophisticated and specialized time-domain measurement and analysis equipment and systems, including transducers, high precision pulser/receiver electronics and analog to digital conversion as well as signal processing to extract the time of flight to the accuracy required. This introduces challenges in integrating these sensing capabilities within a battery module.

It would be a significant enhancement to the current techniques for measuring the state of charge (SoC) and state of health (SoH) of a battery to develop a technique that is less complex to implement, uses equipment readily available in battery electrochemical labs such as oscilloscopes and/or impedance and frequency response analyzers, and can be miniaturized into a measurement system that can be integrated in a battery without a major change in the battery volume or footprint. This is a motivation of the teachings according to the present disclosure.

### SUMMARY

Teachings according to the present disclosure provide a novel and inexpensive in situ frequency-domain technique to determine the acoustic changes in a battery by monitoring the frequency spectra of at least one piezoelectric element (e.g., a piezoelectric transducer) that is acoustically coupled to the battery. A continuous-wave (e.g., sinusoidal wave with a constant amplitude and frequency) electrical excitation signal is applied to the piezoelectric element and its frequency is swept in a range that is expected to include resonant frequency modes (i.e., resonance modes) of the battery. The frequency spectra are provided by a frequency-dependent electrical response to the excitation signal and are shaped by the resonant frequency modes of the battery to include peaks at corresponding frequencies. Shifts in the frequencies of the peaks may include reversible shifts that are representative of the SoC of the battery and irreversible shifts that are representative of the SoH of the battery.

In one aspect, one piezoelectric element (e.g., disk) is acoustically coupled to the battery to form a one-port (piezoelectric) network. The battery acts as an acoustic load which perturbs the impedance of the piezoelectric element and produces features such as peaks (e.g., resonances) in the impedance spectra. Accordingly, monitoring of the state (i.e., SoC and/or SoH) of the battery can be provided by measuring the impedance of the piezoelectric element over a predetermined range of frequencies.

In another aspect, two piezoelectric elements (e.g., disks) are acoustically coupled to the battery to form a two-port (piezoelectric) network. A first piezoelectric element couples acoustic excitation waves to the battery and a second piezoelectric element receives the waves as they travel through (e.g., traverse) the battery. The battery acts as an acoustic transmission line that attenuates (and delays) the coupled acoustic excitation waves and produces peaks in the transmission spectra representing lower attenuations at the resonant frequency modes of the battery. Accordingly, monitoring of the state (i.e., SoC and/or SoH) of the battery can be provided by measuring voltage ratios of the (electrical) excitation signals provided to the first piezoelectric element and electrical signals transduced by the second piezoelectric element over a predetermined range of frequencies.

According to another aspect of the present disclosure, a method for determining a state of an electrochemical cell, the method comprising: acoustically coupling a piezoelectric element to the electrochemical cell; coupling a single frequency acoustic wave to the electrochemical cell and sweeping the single frequency over a predetermined frequency range; based on the sweeping, measuring a frequency-dependent electrical response of the piezoelectric element over the predetermined frequency range to generate a frequency spectrum; identifying a frequency of at least one resonance peak within the generated frequency spectrum, wherein the at least one resonance peak is indicative of a resonant mode of the electrochemical cell; and correlating the identified frequency of the at least one resonance peak to the state of the electrochemical cell, thereby determining the state of the electrochemical cell.

According to yet another aspect of the present disclosure, a system for determining a state of an electrochemical cell is presented, the system comprising: an electrochemical cell; a piezoelectric element acoustically coupled to the electrochemical cell; and a control circuit configured to: generate a continuous-wave electrical excitation signal over a predetermined frequency range, the excitation signal used to generate a single frequency acoustic wave that is coupled to the electrochemical cell, measure a frequency-dependent electrical response of the piezoelectric element over the predetermined frequency range to generate a frequency spectrum; identify a frequency of at least one resonance peak within the generated frequency spectrum, the at least one resonance peak corresponding to a resonant mode of the electrochemical cell; and determine the state of the electrochemical cell based on the identified frequency of the at least one resonance peak.

Further aspects of the disclosure are shown in the specification, drawings and claims of the present application.

### BRIEF DESCRIPTION OF DRAWINGS

The accompanying drawings, which are incorporated into and constitute a part of this specification, illustrate one or more embodiments of the present disclosure and together with the description of example embodiments serve to explain the principles and implementations of the disclosure. Same reference designators refer to same features.

FIG. 1A shows one-port and two-port piezoelectric network configurations according to the present disclosure comprising piezoelectric elements acoustically coupled to a battery and respective one-port and two-port network models.

FIG. 1B shows representative schematic diagrams of the one-port network model and the two-port network model of FIG. 1A.

FIG. 2 shows some exemplary piezoelectric elements and respective modes of vibration.

FIG. 3A shows graphs representative of the effect of changing acoustic velocity and attenuation of the battery on voltage ratio spectra of the two-port piezoelectric network.

FIG. 3B shows graphs representative of the effect of changing acoustic velocity and attenuation of the battery on impedance spectra of the one-port piezoelectric network.

FIG. 4 shows an exemplary implementation of the one-port piezoelectric network and graphs representative of corresponding impedance spectra.

FIG. 5A shows graphs representative of a voltage discharge of the battery of the one-port piezoelectric network of FIG. 4 and corresponding evolution of the impedance spectra.

FIG. 5B shows graphs representative of evolution of resonances in the impedance spectra shown in FIG. 5A over several discharge cycles.

FIG. 6 shows graphs representative of evolution of resonances in the impedance spectra shown in FIG. 5A over a stress test.

FIG. 7 shows a simplified schematic of a system for frequency-domain monitoring of SoC and SoH of a battery via a one-port piezoelectric network comprising a single piezoelectric element acoustically coupled to a battery.

FIG. 8 shows a simplified schematic of a system for frequency-domain monitoring of SoC and SoH of a battery via a two-port piezoelectric network comprising two piezoelectric elements acoustically coupled to a battery.

### DETAILED DESCRIPTION

The references in the present application annotated in brackets and shown in the list of References appended at the end of the present Detailed Description, are incorporated herein by reference in their entirety.

Teachings according to the present disclosure may equally apply to prime (non-rechargeable) or secondary (rechargeable) batteries. As used herein, the term “battery” refers to a device that converts chemical energy into electrical energy through chemical reactions within one or more electrochemical cells of the battery. An electrochemical cell can be considered as the fundamental constituent unit of a battery. As used in the present disclosure, the expressions “electrochemical cell”, “electrochemical battery cell” and “battery cell” may be considered equivalent and intended to refer to a battery (e.g., having a single electrochemical cell).

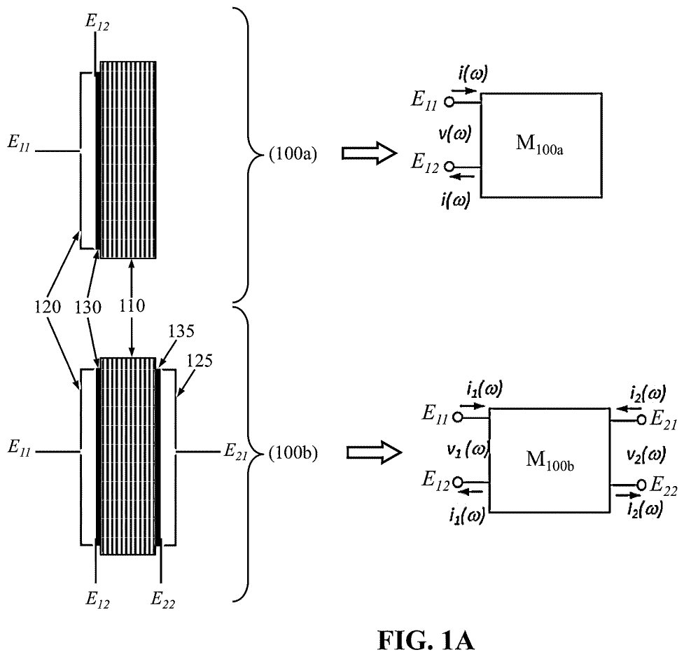

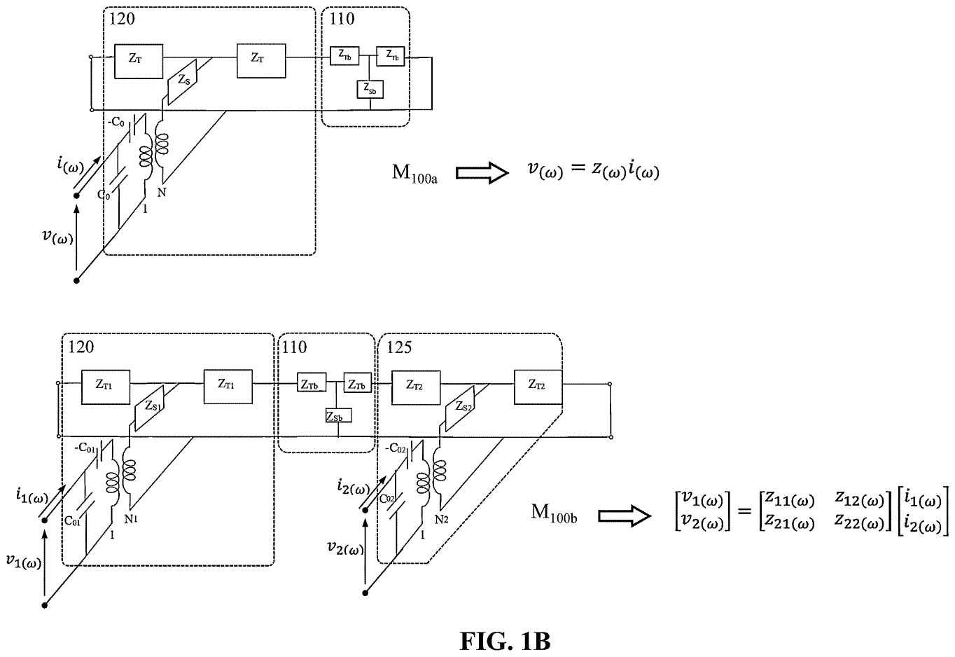

FIG. 1A shows two configurations (e.g., 100a, 100b) according to the present disclosure of piezoelectric elements (e.g., 120, 125) acoustically coupled (e.g., via coupling layer 130) to a battery (e.g., 110). The configuration (100a) can be considered a one-port (piezoelectric) network provided by acoustically coupling the piezoelectric element (120) to the battery (110) and represented by the one-port network model (M₁₀₀ₐ) having a single port for input/output of frequency dependent voltage and current (e.g., v(ω), i(ω), ω is the angular frequency with ω=2πf), the single port provided by two electrodes (E₁₁, E₁₂) of the piezoelectric element (120). Similarly, the configuration (100b) can be considered a two-port (piezoelectric) network provided by acoustically coupling the piezoelectric elements (120) and (125) to the battery (110) and represented by the two-port network model (M_{100b}) having a first port for input/output of frequency dependent voltage and current (e.g., v₁(ω), i₁(ω)), the first port provided by the two electrodes (E₁₁, E₁₂) of the (first) piezoelectric element (120), and a second port for input/output of frequency dependent voltage and current (e.g., v₂(ω), i₂(ω)), the second port provided by two electrodes (E₂₁, E₂₂) of the (second) piezoelectric element (125).

With continued reference to FIG. 1A, a continuous-wave (v(ω), e.g., a sinusoidal wave at the angular frequency ω) electrical excitation signal is applied to the piezoelectric element (120) to generate an acoustic wave (having same angular frequency ω) that is acoustically coupled to the battery (110). An (internal) layered composite structure of the battery (110) dictates acoustic properties of the battery that are anisotropic, including with respect to velocity and attenuation. For example, the acoustic properties in plane (e.g., parallel to the layers) may be dominated by the fastest layer whereas the acoustic velocity perpendicular to the layers may be an average of the velocities of the various layers (assuming layers of a same thickness). Accordingly, for the coupled acoustic wave to excite a specific resonant frequency mode of the battery (110), teachings according to the present disclosure may predetermine (e.g., via modeling and simulation as described below in the present disclosure) a placement/orientation of the piezoelectric element (120) relative to (the layered composite structure of) the battery, as well as appropriate geometry, material and bonding (e.g., coupling layer 130) of the piezoelectric element (120).

Furthermore, measurable physical changes may occur in the materials that make the layered composite structure of the battery (110) during charging and/or discharging. These include changes that may be on the order of 30 percent or greater in the density, elasticity, and acoustic velocity of these materials, all of which change the battery materials acoustic properties. In turn, such changes in the acoustic properties of the battery (110) may cause shifts in the resonant frequency modes of the battery, including reversible shifts that may correlate to the state of charge (SoC) and irreversible shifts that may correlate to the state of health (SoH) of the battery (110).

Teachings according to the present disclosure may use the one-port piezoelectric network (100a) or the two-port piezoelectric network (100b) for measuring/monitoring the shifts in the resonant frequency modes of the battery and therefore determining of the SoC and/or the SoH of the battery (110). The resonant frequency modes of the battery may be recognized through peaks measured in the frequency spectra of the piezoelectric networks (100a) and (100b). These may include peaks in the impedance spectra (e.g., v(ω)/i(ω) for different values of the angular frequency ω) of the one-port piezoelectric network (100a) or peaks in the (complex) voltage ratio spectra (e.g., v₂(ω)/v₁(ω) for different values of the angular frequency ω) of the two-port piezoelectric network (100b).

In the case of the one-port piezoelectric network (100a), the battery (110) is an acoustic load which perturbs the impedance (e.g., v(ω)/i(ω) measured across the two electrodes (e.g., E₁₁, E₁₂) of the piezoelectric element (120) and produces features such as peaks in the impedance spectra that reflect the velocity and attenuation in the layered composite structure of the battery (110) corresponding to the various resonant frequency modes. In the case of the two-port piezoelectric network (100b), the battery (110) acts as an acoustic transmission line coupled between the two piezoelectric elements (120) and (125) that perturbs the voltage ratio (e.g., v₂(ω)/v₁(ω) measured across the two pairs of electrodes E₁₁, E₁₂ and E₂₁, E₂₂) and produces features such as peaks in the voltage ratio spectra that reflect the velocity and attenuation in the layered composite structure of the battery (110) corresponding to the various resonant frequency modes.

FIG. 1B shows representative schematic diagrams of the one-port network model (M₁₀₀ₐ) and the two-port network model (M_{100b}) of FIG. 1A. These include respective (electro-acoustic) models of the piezoelectric elements, (120) and (125), and (acoustic) model of the battery (110). For example, models of the piezoelectric elements (120) and (125) may be represented by parameters that include electrical impedances (e.g., capacitors C₀₁, C₀₂ and inductors/coils 1 and N₁, N₂) coupled to acoustic impedances (e.g., Z_{S1}, Z_{T1} and Z_{S2}, Z_{T2}), and the model of the battery (110) may be represented by parameters that include acoustic impedances (e.g., Z_{Sb}, Z_{TB}). Corresponding one-port and two-port network parameters of the models (M₁₀₀ₐ) and (M_{100b}), including (complex) impedances (e.g., Z(ω) and Zᵢⱼ(ω)), are also shown in FIG. 1B.

With continued reference to FIG. 1B, it is noted that the theory behind the models is well known (e.g., Refs. [4a] and [4b]) and has been used, for example, to measure the velocities in thin polymer layers and the curing of epoxy (e.g., Ref. [5]). The parameters of the models of the piezoelectric elements (120 and 125, e.g., in the thickness mode) can be found, for example, in [e.g., Refs. [4a] and [4b]). The parameters of the model of the battery (110) can be determined, for example, from the effective acoustic velocity in the thickness direction of the battery, v_{b}, the battery density, ρ_{b}, the area, A, of the battery in contact with the piezoelectric element(s), and the thickness of the battery. These may allow to derive a specific (acoustic) impedance, Z_{b}, of the battery (110), provided by Z_{b}=v_{b}·ρ_{b}·A, from which functions for the parameters Z_{Tb} and Z_{Sb} can be provided by Z_{Tb}=i·Z_{b}·tan(ωt/2v_{b}) and Z_{Sb}=−i·Z_{b}·csc(ωt/v_{b}).

Although details related to the derivation of the models of FIG. 1B may be considered outside the scope of the present disclosure, this may include destructive physical analysis (DPA). For example, DPA of the battery (110) may determine the specific geometries (dimensions, thicknesses) of the internal layered structures, including those corresponding to the electrolyte, anode, separator and cathode materials, which can serve as inputs to the development of a high-fidelity finite element model (FEM) of the battery using available tools. Further input to the FEM may be provided by incorporating the appropriate acoustic material properties, including previously determined densities and elastic properties of materials used in the battery (110) and the coupling layer (130).

The ability to model the acoustic properties of the battery (110) has allowed inventors of the present disclosure to determine the appropriate placement/orientation of the piezoelectric elements (e.g., 120, 125 of FIG. 1A) relative to (the layered composite structure of) the battery (110), as well as appropriate geometry, material, and bonding (e.g., coupling layer 130) of the piezoelectric elements, so as to excite specific resonant frequency modes in the battery (110). Because this can be achieved (e.g., via simulation) in the FEM prior to implementing/realizing the one-port and two-port (piezoelectric) networks (100a) and (100b), optimization for different types and shapes of batteries can be streamlined.

As described above in the present disclosure, the one-port and two-port piezoelectric networks (100a) and (100b) may be produced by connecting mechanically, via the coupling layer (130, e.g., epoxy or an acoustic couplant) at least one (inexpensive) piezoelectric element (120 and/or 125, e.g., a piezoelectric resonator) to at least one surface of the battery (110) to generate an acoustic wave for excitation of resonant frequency modes in the battery's layered composite structure and monitor/measure changes (e.g., shift in the resonant frequencies) which are due to changes of the elastic properties of (the layered composite structure of) the battery (110) and may be correlated to the state of charge (SoC) and the state of health (SoH). Because the battery (110) is a very anisotropic structure, the acoustic velocities are dependent on the direction and mode of excitation of the battery.

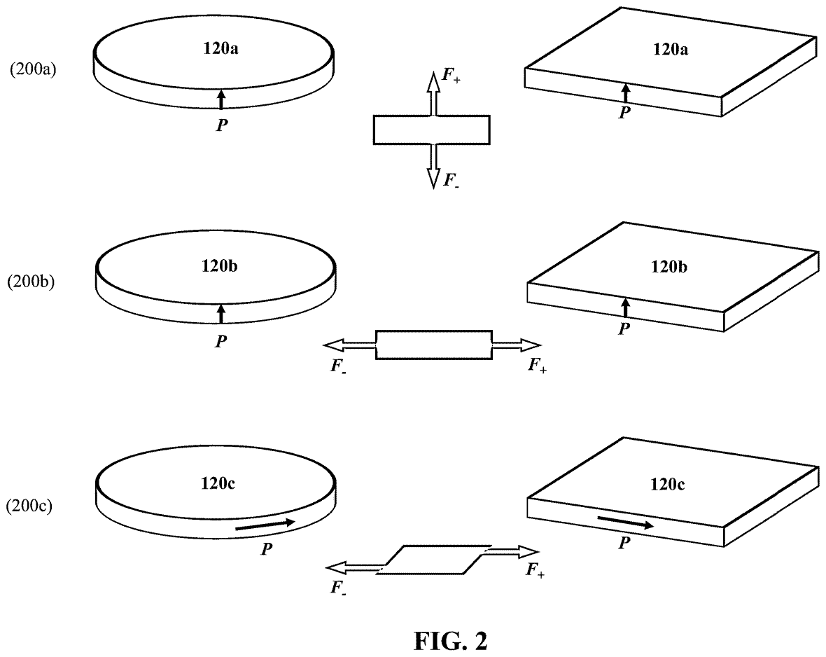

It follows that teachings according to the present disclosure allow for the piezoelectric element (e.g., 120 and/or 125) to be designed to excite a variety of different resonant frequency modes of the battery. FIG. 2 shows some commonly known modes of vibration of a (planar) piezoelectric element that could be used to excite a variety of different resonant frequency modes in a battery. Although FIG. 2 shows an exemplary planar piezoelectric element (e.g., disk) that may be suited to support excitations of batteries having a planar/flat outer surface (e.g., at least a portion thereof), non-planar piezoelectric elements/structures may be envisioned to support excitations of batteries with non-planar (outer) geometries, including cylindrically shaped batteries and/or batteries having curved surfaces. Nonlimiting exemplary non-planar piezoelectric structures may include radially polled cylinders (e.g., Ref. [6]), flexible polymer (e.g., Ref. [7]) or 1-3 piezoelectric composites (Ref. [8]).

It is noted that choice of material and geometry of the coupling layer (130) may be considered crucial for determining how acoustic energy (e.g., acoustic waves, vibrations, stress) generated by the piezoelectric element (e.g., 120) is transferred into the battery (110). The choice of the material and geometry of the coupling layer (130) depends on a specific type of acoustic mode (e.g., thickness, extensional/compressional, lateral, radial, shear) that is to be excited within the battery (110). For example, a viscous/gel couplant may be used to transmit extensional/compressional waves into the battery (110) while dissipating shear waves, whereas a stiff couplant (e.g., epoxy) can form a rigid bond to transmit both extensional/compressional and shear waves thereby allowing excitation of a wider variety of wave modes in the battery (110).

FIG. 2 shows some exemplary modes of vibration (e.g., 200a, 200b, 200c) of piezoelectric elements (e.g., 120a, 120b, 120c) that may be used in the one-port and/or two-port piezoelectric networks (e.g., 100a, 100b of FIG. 1A) according to the present teachings. A thickness mode of vibration (200a) may be provided by the piezoelectric element (120a) that can include a round or a square surface, a polarization vector, P, that is along a thickness of the piezoelectric element (120a) and normal to the surface, and a vibration/displacement direction provided by colinear vectors, F₊ and F_{·}, that are also normal to the surface of the piezoelectric element (120a) and can therefore cause the surface of the piezoelectric element to expand and contract. A lateral mode of vibration (200b) may be provided by the piezoelectric element (120b) that can include a round or a square surface, a polarization vector, P, that is along a thickness of the piezoelectric element (120a) and normal to the surface, and a vibration/displacement direction provided by colinear vectors, F₊ and F_{·}, that are parallel to the surface of the piezoelectric element (120b) and can therefore generate an in-plane motion at the surface of the piezoelectric element. A shear mode of vibration (200c) may be provided by the piezoelectric element (120c) that can include a round or a square surface, a polarization vector, P, that is parallel to the surface of the piezoelectric element (120a), and a vibration/displacement direction provided by non-colinear parallel vectors, F₊ and F_{·}, that are parallel to the surface of the piezoelectric element (120b) and can therefore generate torsional or edge-based motion.

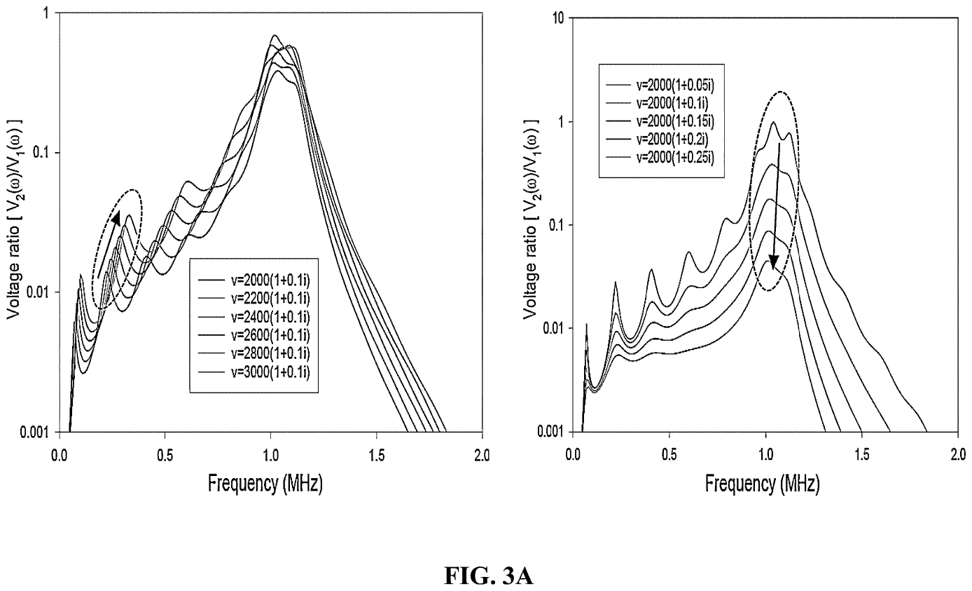

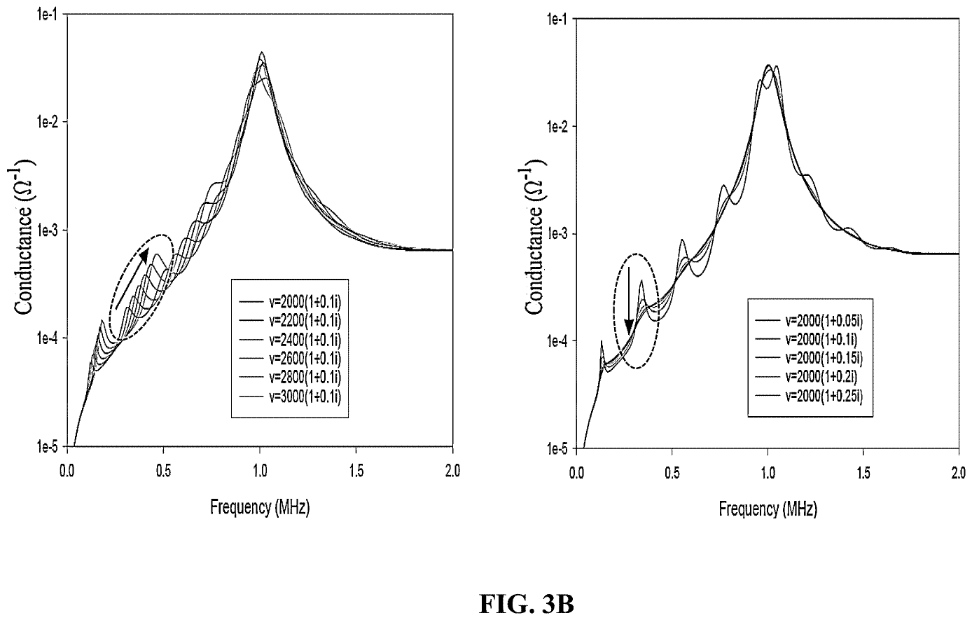

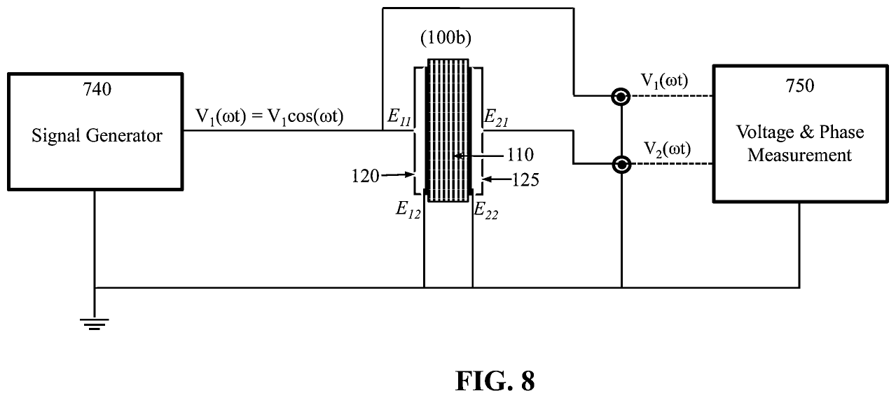

FIG. 3A shows graphs representative of the effect of changing acoustic velocity and attenuation of the battery (110) on voltage ratio spectra of the two-port piezoelectric network (100b, e.g., in thickness mode). These include frequency domain measurement of the voltage ratio (e.g., v₂(ω)/v₁ (ω)) of the voltages v₁(ω) and v₂(ω) at the respective ports of the two-port piezoelectric network (100b) as a function of the frequency (frequency f, with ω=2πf). For example, as shown in FIG. 8, the (input) voltage v₁(ω) may be provided by a continuous-wave AC signal with a fixed voltage amplitude (e.g., v₁(ω)=V₁(ω) with V₁=1 volt) and at a given frequency that is applied via a signal/function generation (740) at the first port (e.g., across electrodes E₁₁ and E₁₂) of the two-port piezoelectric network (100b). Accordingly, as shown in FIG. 8, a corresponding (output) second voltage v₂(ω)=V₂(ωt) may be obtained/measured via a voltage and phase measurement circuit block (750, e.g., an oscilloscope) at the second port (e.g., across electrodes E₂₁ and E₂₂) of the two-port piezoelectric network (100b), which can be used to measure the ratio between the two voltages, v₁(ω) and v₂(ω), at the given frequency. By repeating the applying and the measuring for different frequencies within a frequency range (e.g., 0.1 MHz to 2.0 MHz), the voltage ratio spectra shown in FIG. 3A can be obtained.

It is noted that the voltage ratio spectra represented in the graphs of FIG. 3A (and FIG. 3B described below) may be based simulation data generated via the corresponding two-port model (M_{100b}) described above with reference to FIG. 1B. This can include a model of the piezoelectric elements (e.g., disks) having a diameter of 0.02 m and a thickness of 0.002 m. The properties of the piezoelectric are shown in below Table 1. The model of the battery can be based on a battery having a thickness of 0.005 m, a nominal density of 2000 kg/m³, and a transverse electric (TE) mode velocity of 2200 m/s with an attenuation factor Q of 5.

TABLE 1

| Property | | Value | |
|---|---|---|---|
| Density of Piezoelectric | (kg/m³) | 7800 | |
| Density of battery | (kg/m³) | 2000 | |
| Area of piezoelectric on wall | (m²) | 3.141 × 10⁻⁴ | |
| Battery thickness | (m) | 0.005 | |
| Input Piezoelectric thickness | (m) | 0.002 | |
| Receive Piezoelectric thickness | (m) | 0.002 | |
| Piezoelectric Coefficient e₃₃ | (C/m²) | 23.3 | (1 − 0.005 i) |
| Permittivity ε₃₃^{S} | (F/m) | 1.505 × 10⁻⁸ | (1 − 0.02 i) |
| Elastic stiffness at constant Field c₃₃^{D} | (N/m²) | 15.9 × 10¹⁰ | (1 + 0.01 i) |
| Thickness Coupling | | 0.476 | (1 − 0.0029 i) |
| Velocity of the battery v_{b} | (m/s) | 2200 | (1 + 0.1 i) |

Voltage ratio spectra obtained by simulating (e.g., via above-described models) changes in the acoustic velocity property of the battery and plotted as separate graphs (one for each acoustic velocity) are shown on the left side of FIG. 3A, and voltage ratio data obtained by simulating (e.g., via above-described models) changes in the acoustic attenuation property of the battery and plotted as separate graphs (one for each acoustic attenuation) are shown on the right side of FIG. 3A. It is noted that the acoustic velocity (of an acoustic wave propagating) through the battery may be represented by a complex number having a real part indicative of an effective acoustic velocity (e.g., TE mode) and an imaginary part indicative of an effective attenuation (e.g., Q factor).

As shown in the left side graphs of FIG. 3A, different values of the acoustic velocity of the battery provide for different peaks in the voltage ratio spectra corresponding to different resonant frequency modes of the battery. For example, as can be seen in the encircled region of the graphs corresponding to a specific resonant mode, for increasing values of the acoustic velocity (e.g., real part of the velocity v in a range of 2000 to 3000) the voltage ratio at the resonant mode increases while the frequency of the resonant mode also increases. Same behavior with respect to increasing values of the acoustic velocity can be observed for other resonant modes (e.g., graphs show common distinguishing peaks at about 4 different resonant modes).

As shown in the right side graphs of FIG. 3A, different values of the acoustic attenuation of the battery provide for different peaks in the voltage ratio spectra corresponding to different resonant frequency modes of the battery. For example, as can be seen in the encircled region of the graphs corresponding to a specific resonant mode, for increasing values of the acoustic attenuation (e.g., imaginary part of the velocity v varies by a factor in a range of 0.05 to 0.25) the voltage ratio at the resonant mode decreases while the frequency of the resonant mode remains substantially constant. Same behavior with respect to increasing values of the acoustic attenuation can be observed for other resonant modes (e.g., graphs show common distinguishing peaks at about 4 different resonant modes).

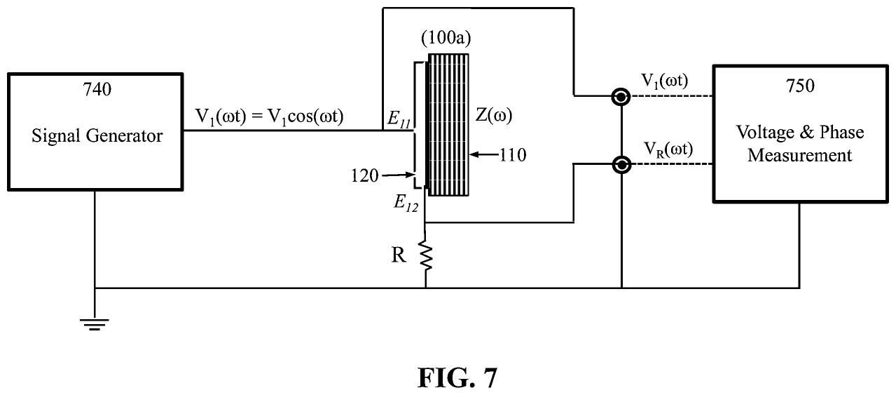

FIG. 3B shows graphs representative of the effect of changing acoustic velocity and attenuation of the battery on impedance spectra of the one-port piezoelectric network (100a, e.g., in thickness mode). These include frequency domain measurement of the (complex) impedance (e.g., v(ω)/i(ω)) seen at the single port of the one-port piezoelectric network (100a) as a function of the frequency (frequency f, with ω)=2πf). For example, as shown in FIG. 7, the (input) voltage v(ω) may be provided by a continuous-wave AC signal with a fixed voltage amplitude (e.g., V₁(ωt) with V₁=1 volt) and at a given frequency that is applied between the electrode E₁₁ and a reference ground via a signal/function generation (740), and a reference resistor, R, with a known resistance is connected between the electrode E₁₂ and the reference ground. Accordingly, as shown in FIG. 7, the (complex) impedance (e.g., impedance between E₁₁ and E₁₂) may be obtained/measured (e.g., via a voltage and phase measurement circuit block 750, e.g., an oscilloscope) by measuring respective amplitudes and phases of voltages (e.g., V₁(ωt) and V_{R}(ωt) of FIG. 7) between each of the electrodes, E₁₁ and E₁₂, and the reference ground, and thereby their difference to obtain the impedance. It is noted that the impedance spectra represented in the graphs of FIG. 3B may be based simulation data generated via modelling of a piezoelectric and a battery similar to the modelling described above with reference to FIG. 3A.

As shown in the left side graphs of FIG. 3B, different values of the acoustic velocity of the battery provide for different peaks in the conductance (i.e., inverse of impedance) spectra corresponding to different resonant frequency modes of the battery. For example, as can be seen in the encircled region of the graphs corresponding to a specific resonant mode, for increasing values of the acoustic velocity (e.g., real part of the velocity v in a range of 2000 to 3000) the conductance at the resonant mode increases while the frequency of the resonant mode also increases. Same behavior with respect to increasing values of the acoustic velocity can be observed for other resonant modes (e.g., graphs show common distinguishing peaks at about 4 different resonant modes).

As shown in the right side graphs of FIG. 3B, different values of the acoustic attenuation of the battery provide for different peaks in the conductance spectra corresponding to different resonant frequency modes of the battery. For example, as can be seen in the encircled region of the graphs corresponding to a specific resonant mode, for increasing values of the acoustic attenuation (e.g., imaginary part of the velocity v varies by a factor in a range of 0.05 to 0.25) the conductance at the resonant mode decreases while the frequency of the resonant mode remains substantially constant. Same behavior with respect to increasing values of the acoustic attenuation can be observed for other resonant modes (e.g., graphs show common distinguishing peaks at about 4 different resonant modes).

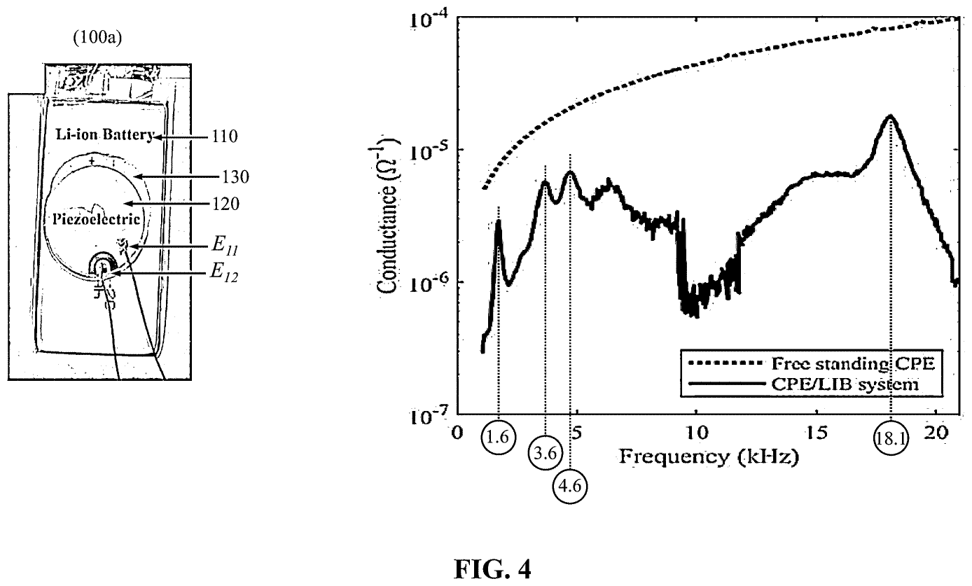

The graphs shown in FIG. 3A and FIG. 3B show that frequency domain monitoring/measuring of changes in acoustic properties, and therefore state of charge (SoC) and/or state of health (SoH), of a battery can be provided via the one-port or two-port piezoelectric networks according to the present teachings. Furthermore, because elements of the present networks can be accurately modeled, simulation data can be used for streamlining and optimizing design and implementation of the one-port and/or two-port piezoelectric networks according to the present teachings for a target battery. One exemplary implementation and proof of concept is shown in FIG. 4.

FIG. 4 shows an exemplary implementation of the one-port piezoelectric network (e.g., 100a of FIG. 1A) and graphs representative of corresponding impedance (e.g., conductance) spectra. The exemplary implementation of FIG. 4 is provided by a (lithium-ion) battery (110, LIB) whose case is acoustically attached to a thin (e.g., thickness of 0.5 mm) piezoelectric element (120, e.g., ceramic piezoelectric disk, CPE) via a standard epoxy (e.g., coupling layer 130). Data representing impedance spectra measured over a frequency range of 1-21 kHz are plotted in a graph shown in FIG. 4, including data for the free-standing CPE (without coupling to the LIB) and data for the one-port piezoelectric network (100a), respectively plotted via dotted and solid line graphs. As shown, no pronounced peaks are seen in data corresponding to the free-standing CPE whereas pronounced peaks are seen at the frequencies of 1.6 kHz, 3.6 kHz, 4.6 kHz and 18.1 kHz for the one-port piezoelectric network (100a). It is noted that peaks in the data may represent frequencies of resonant modes. In the case of the (free-standing) CPE, resonant modes may be present outside the shown frequency range. In general, teachings according to the present disclosure may not restrict the piezoelectric elements (e.g., 120,125) to include specific resonant modes so long the corresponding frequencies do not overlap/coincide a frequency region within which shifts of resonant modes measured/monitored by the one-port or two-port piezoelectric networks according to the present disclosure reside.

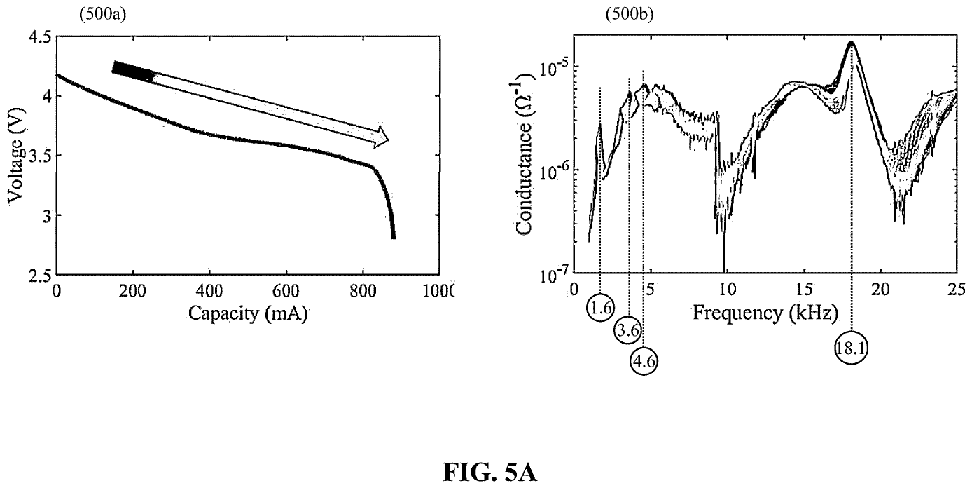

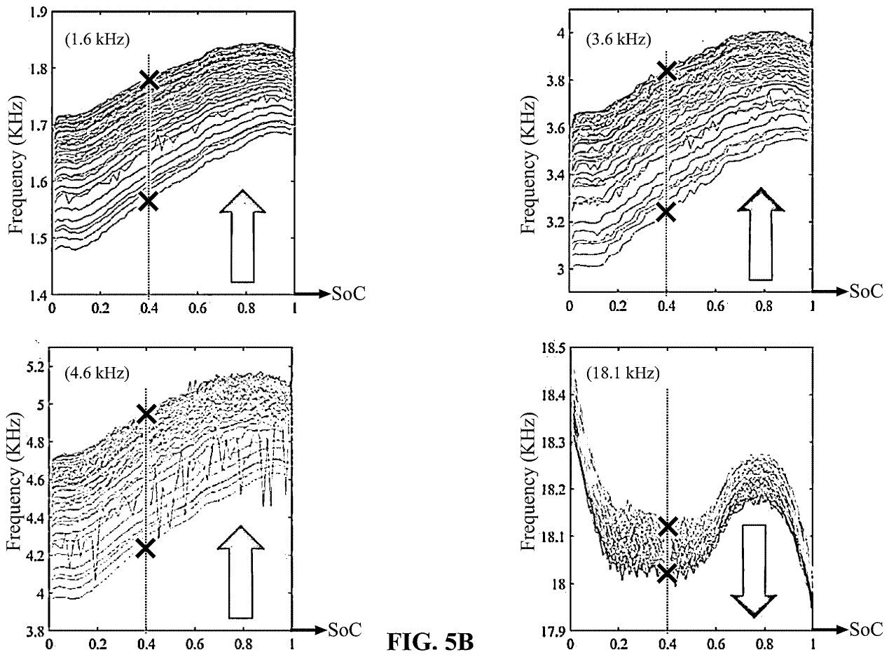

FIG. 5A shows graphs representative of a voltage discharge of the battery (110) of the one-port piezoelectric network (100a) of FIG. 4 and corresponding evolution of the impedance (e.g., conductance) spectra measured in-operando (e.g., during charging and/or discharging of the battery). In particular, the graph (500a) of FIG. 5A represents the voltage discharge curve of the battery (110, e.g., voltage versus capacity used over time), or in other words, the state of charge (SoC) of the battery (110). On the other hand, the (superimposed) graphs (500b) of FIG. 5A represent impedance spectrum curves measured during the discharge of the battery (110) where the darker curves correspond to earlier times in the discharge (less of the overall available capacity used) and the lighter curves to later times (more of the overall available capacity used). As shown in FIG. 5A, as the battery discharges, the frequencies of the resonant modes (peaks) shift significantly. Peaks at the 1.6 kHz, 3.6 kHz, and 4.6 kHz shift to lower frequencies by 11.3%, 15.9%, and 13.7%, respectively, which suggests a bulk softening of (the layered composite structure of) the battery (110). On the other hand, behavior of the peak around the 18.1 kHz resonant frequency differs significantly, showing a more pronounced decrease in the peak amplitude (i.e., conductance) and less of a shift of its frequency. The consistency in behavior of the peaks at the three lower frequencies allow to correlate the state of charge (SoC) of the battery (110) with the corresponding (shifts of) frequencies. Furthermore, consistency in the amplitude of the peaks at the three lower frequencies (and also at the 18.1 KHz frequency) can allow correlation of the state of charge (SoC) of the battery (110) with the corresponding (shifts of) amplitudes.

FIG. 5B shows graphs representative of evolution of resonances (e.g., peaks) in the impedance spectra (e.g., 500b) shown in FIG. 5A over fifty full discharge cycles of the battery (110). Graphs (1.6 kHz), (3.6 kHz), (4.6 kHz) and (18.1 kHz) respectively represent evolution, over the age of the battery (110), of the dependencies of the (identified) resonant frequencies 1.6 kHz, 3.6 kHz, 4.6 kHz and 18.1 kHz on the state of charge (SoC) of the battery (110) over the age of the battery, as the battery cycles/ages over the fifty discharge cycles. Light colors indicate early cycles, and dark colors indicate later cycles. As shown in FIG. 5B, over the longer term, the 1.6 kHz, 3.6 kHz, and 4.6 kHz resonances initially increase in frequency (e.g., for a given SoC as indicated by the two crosses in the graphs) before stabilizing to a certain (peak) frequency, which suggests a mechanical stiffening of the battery (110) that is independent from the SoC. Inventors of the present disclosure attribute this mechanical stiffening to solid electrolyte interface (SEI) growth and the associated electrolyte consumption in the layered composite structure of the battery (110). The 18.1 kHz peak continues its different behavior by decreasing in frequency as a function of both the SoC and cycle number. These graphs further show the ability to correlate the state of charge (SoC) of the battery (110) with the (lower) frequencies of the peaks. On the other hand, the suggested mechanical stiffening of the battery (110) being independent from the SoC may be advantageously used as an indication of state of health (SoH) of the battery.

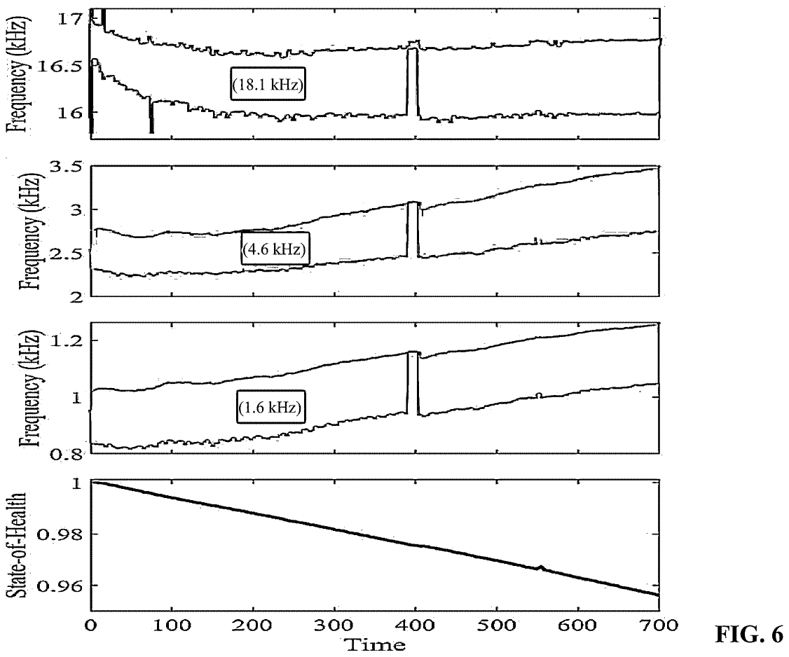

FIG. 6 shows graphs representative of (in-operando) evolution of resonances in the impedance spectra shown in FIG. 5A over a stress test that includes high temperature (e.g., 45° C.) and high-rate (e.g., 1 C rate with battery fully charged/discharged in one hour). These graphs may be representative of the effect of mechanical changes in the battery (110) due to aging over the resonances (identified per FIG. 5A) and therefore may be used for assessing state of health (SoH) of the battery. Inventors of the present disclosure have established that all the identified resonances decrease in frequency and the 3.6 kHz resonance decreases in amplitude to the point where it is difficult to extract information (e.g., using the impedance spectra) below a state of charge (SoC) of 50%. However, because the 3.6 kHz resonance follows a same trend as the 1.6 kHz and 4.6 kHz resonances, it can be neglected (and therefore not represented in the graphs of FIG. 6) without sacrificing the capability in assessing the SoH of the battery (110). It is noted that at approximately the 400 hours mark a glitch in the measurement system caused a short gap in the data as shown in the graphs of FIG. 6. In the graphs of FIG. 6, the top of the envelope represents an SoC of 100% and the bottom of the envelope an SoC of 0%.

As shown in the 18.1 kHz graph of FIG. 6, the resonance decreases by about 0.3 kHz during the first 100 hours of the experiment before stabilizing then slightly increases over time. As before, this resonance deviates in behavior when compared to the other lower frequency resonances. On the other hand, the 1.6 kHz and 4.6 kHz graphs show some initial fluctuations before increasing significantly after 300 hours. Inventors of the present disclosure attribute the increase in the resonant frequency of the 1.6 kHz, 4.6 kHz (and 3.6 kHz not shown) resonances to a stiffening of the layered composite structure of the battery (110) because of excessive SEI growth and electrolyte consumption.

The above results described with reference to the graphs of FIG. 5A/5B and FIG. 6 confirm that the SoC and SoH of a battery (e.g., lithium-ion battery) can be correlated with the frequencies of the resonant modes measured by the one-port (and/or two-port) piezoelectric network (100a, and/or 100b) according to the present teachings. These results can form the basis for a frequency domain monitoring/measuring device according to the present disclosure that that can be used to independently assess the state of charge (SoC) and state of health (SoH) of a battery without need for a direct electrical measurement of the battery. Some exemplary implementations of such device are described below with reference to FIG. 7 and FIG. 8, with further description provide above with reference to FIG. 3A and FIG. 3B. These devices allow implementation of frequency domain techniques that use frequency measurements to calculate the complex impedance Z(ω) or complex voltage ratio α(ω) and then sweep to the next frequency for another frequency measurement, thereby generating the frequency spectrum of the quantities Z(ω) or a (ω). Peak frequencies and amplitudes in these spectra then shift in frequency and amplitude due to changes in the acoustic properties of the internal layers of the battery. Reversible changes can be correlated with the state of charge (SoC) and irreversible changes (or chaotic changes) can be correlated with the state of health (SoH) of the battery.

As shown in FIG. 7 and FIG. 8, a device (e.g., system) according to the present disclosure for assessing the state of charge (SoC) and/or state of health (SoH) of a battery (e.g., 110) can include a signal generator circuit (740, circuit block) for generation of a continuous-wave AC signal, V₁(ωt)=V₁ cos(ωt), having an arbitrary fixed voltage amplitude, V₁, and an angular frequency, ω, that is applied between an electrode (e.g., E₁₁) of a piezoelectric element (120, e.g., actuator) and a reference ground for coupling of a corresponding (single frequency, single tone) acoustic wave to the battery (110).

In the configuration shown in FIG. 7, the piezoelectric element (120) is acoustically coupled to the battery (110) to form a one-port piezoelectric network (100a) and the assessing of the SoC and SoH is provided by measuring/monitoring frequencies of resonant modes in the electrical impedance of the one-port piezoelectric network (100a) with the help of a reference resistor, R, having a known resistance that is coupled between the other electrode (e.g., E₁₁) of the (actuation) piezoelectric element (120) and the reference ground. A voltage and phase measurement circuit (750, circuit block) measures voltages V₁(ωt) and V_{R}(ωt) at the first and second electrodes, E₁₁ and E₁₂, and uses respective amplitudes and phase information to derive the (complex) electrical impedance between the first and second electrodes, E₁₁ and E₁₂. By sweeping the frequency of the input excitation signal, V₁(ωt), impedance spectra and corresponding resonances can be tracked/measured. The impedance, Z(ω), that is equal to the voltage between the two electrodes, E₁₁ and E₁₂, divided by the current through the two electrodes, E₁₁ and E₁₂, can be determined from the expression:

$$\begin{matrix}Z ( ω ) = R [ {V}_{1} ( ω ) cos ( ω t ) - {V}_{R} ( ω ) cos ( ω t + θ ( ω ) ] / [ {V}_{R} ( ω ) cos ( ω t + θ ( ω ) ] \\ = R [ {V}_{0} ( ω ) / {V}_{R} ( ω ) ) exp ( - i θ ( ω ) ) - 1 ]\end{matrix}$$

where the quantity ωt is treated as a phasor. In phasor notation the term cos (ωt) can be removed and the voltage can be written as V_{R}(ω) ∠θ(ω) which is represents an amplitude V_{R} and phase angle θ at the frequency ω.

In the configuration shown in FIG. 8, the piezoelectric element (120) is acoustically coupled to the battery (110) and an addition piezoelectric element (125) is acoustically coupled to (e.g., an opposite side of) the battery (110) to form a two-port piezoelectric network (100b), and the assessing of the SoC and SoH is provided by measuring/monitoring, with the voltage and phase measurement circuit (750), frequencies of resonant modes in the (complex) voltage ratio of voltages at the respective (first) electrodes (e.g., E₁₁ and E₂₁) of the two piezoelectric elements (120) and (125). It noted that in such configuration, the respective (second) electrodes (e.g., E₁₂ and E₂₂) of the two piezoelectric elements (120) and (125) are connected to the reference ground. In this case, the voltage ratio, a (ω), of the received voltage, V₂(ωt), at the electrode, E₂₁, to the applied voltage, V₁(ωt), at the electrode, E₁₁, can be determined from the expression:

$$α ( ω ) = {V}_{1} ( ω ) cos ( ω t ) / {V}_{0} ( ω ) cos ( ω t + θ ( ω ) ] = ( {V}_{1} ( ω ) / {V}_{0} ( ω ) ) exp ( - i θ ( ω ) )$$

where the quantity θ(ω) is a frequency dependent phase (e.g., delay) that is based on a velocity in the battery (110) along a path between the two piezoelectric elements (120) and (125).

It is noted that although the voltage and phase measurement circuit (750) shown in FIG. 7 and FIG. 8 may include substantially same functionalities, in some implementations some additional functionalities/features may be used. For example, in the configuration of FIG. 8, added performance/precision in measuring the voltage ratio may be provided by including a lock-in amplifier that is synched to the input signal, V₁(ωt), so to reduce noise and accurately determine the phase θ(ω) which is a measure of the velocity in the battery (110) along the path between the two piezoelectric elements (120) and (125). In some implementations memory devices may be included to store measurement results which can be compared to establish trends, such as shifts in frequencies of the resonant modes and/or amplitudes of corresponding peaks, that can be used to assess SoC and/or SoH. In such implementations, such memory devices may further include expected frequency locations (e.g., as identified in FIG. 4 or via modeling) of the resonant modes to allow interrogation of the impedance and/or voltage ratios only in narrower frequency ranges about the expected frequency location. According to yet another implementation, a communication interface may be included so to replace or complement features provided through the described memory devices. Other flexibility in features and functionalities may be provided in dependence of design and/or performance goals. All such features and functionalities may be integrated in one integrated circuit that is coupled to the one-port or two-port piezoelectric network (100a) or (100b).

A number of embodiments of the disclosure have been described. Nevertheless, it will be understood that various modifications may be made without departing from the spirit and scope of the present disclosure. Accordingly, other embodiments are within the scope of the following claims.

The examples set forth above are provided to those of ordinary skill in the art as a complete disclosure and description of how to make and use the embodiments of the disclosure and are not intended to limit the scope of what the inventor/inventors regard as their disclosure.

Modifications of the above-described modes for carrying out the methods and systems disclosed herein that are obvious to persons of skill in the art are intended to be within the scope of the following claims. All patents and publications mentioned in the specification are indicative of the levels of skill of those skilled in the art to which the disclosure pertains. All references cited in this disclosure are incorporated by reference to the same extent as if each reference had been incorporated by reference in its entirety individually.

It is to be understood that the disclosure is not limited to particular methods or systems, which can, of course, vary. It is also to be understood that the terminology used herein is for the purpose of describing particular embodiments only and is not intended to be limiting. As used in this specification and the appended claims, the singular forms “a,” “an,” and “the” include plural referents unless the content clearly dictates otherwise. The term “plurality” includes two or more referents unless the content clearly dictates otherwise. Unless defined otherwise, all technical and scientific terms used herein have the same meaning as commonly understood by one of ordinary skill in the art to which the disclosure pertains.

### REFERENCES

[1] Ali, M. U., Zafar, A., Nengroo, S. H., Hussain, S., Junaid Alvi, M. and Kim, H. J., 2019. Towards a smarter battery management system for electric vehicle applications: A critical review of lithium-ion battery state of charge estimation. Energies, 12(3), p. 446.
[2] Ladpli et al., Estimating state of charge and health of lithium-ion batteries with guided waves using built-in piezoelectric sensors/actuators. Journal of Power Sources, 384 (2018) 342-354.
[3] Davies et al., State of Charge and State of Health Estimation Using Electrochemical Acoustic Time of Flight Analysis. Journal of The Electrochemical Society, 164 (12) A2746-A2755 (2017).
[4a] Sherrit, Stewart, et al. “Comparison of the Mason and KLM equivalent circuits for piezoelectric resonators in the thickness mode.” 1999 IEEE Ultrasonics Symposium. Proceedings. International Symposium (Cat. No. 99CH37027). Vol. 2. IEEE, 1999.
[4b] Sherrit, S., Lee, H. J., Bao, X., Badescu, M. and Bar-Cohen, Y., 2020 April. Composite piezoelectric resonator 1D modeling with loss. In Behavior and Mechanics of Multifunctional Materials IX (Vol. 11377, pp. 130-144). SPIE.
[5] Sherrit, S., Olazabal, V., Sansinena, J. M., Bao, X., Chang, Z. and Bar-Cohen, Y., 2002 July. Use of piezoelectric resonators for the characterization of mechanical properties of polymers. In Smart Structures and Materials 2002: Electroactive Polymer Actuators and Devices (EAPAD) (Vol. 4695, pp. 262-276). SPIE.
[6] Tasker, Ron, Marc Lukacs, Mike Sayer, and Stewart Sherrit. “Techniques to determine the complex material constants of spherical and cylindrical ring resonators.” In 1999 IEEE Ultrasonics Symposium. Proceedings. International Symposium (Cat. No. 99CH37027), vol. 2, pp. 987-990. IEEE, 1999.
[7] Sherrit, S., Haysom, J. E., Wiederick, H. D., Mukherjee, B. K. and Sayer, M., 1996 August. Frequency dispersion and field dependence in the material constants of PVDF-TrFE copolymers in the thickness mode. In ISAF′96. Proceedings of the Tenth IEEE International Symposium on Applications of Ferroelectrics (Vol. 2, pp. 959-962). IEEE.
[8] Sherrit, S., Wiederick, H. D. and Mukherjee, B. K., 1997 November. Complete matrix of the piezoelectric, dielectric, and elastic material constants of 1-3 piezoelectric ceramic/polymer composites. In Smart Materials, Structures, and Integrated Systems (Vol. 3241, pp. 327-337). SPIE.

1. A method for determining a state of an electrochemical cell, the method comprising:
acoustically coupling a piezoelectric element to the electrochemical cell;
coupling a single frequency acoustic wave to the electrochemical cell and sweeping the single frequency over a predetermined frequency range;
based on the sweeping, measuring a frequency-dependent electrical response of the piezoelectric element over the predetermined frequency range to generate a frequency spectrum;
identifying a frequency of at least one resonance peak within the generated frequency spectrum, wherein the at least one resonance peak is indicative of a resonant mode of the electrochemical cell; and
correlating the identified frequency of the at least one resonance peak to the state of the electrochemical cell, thereby determining the state of the electrochemical cell.

2. The method according to claim 1, wherein:
the state of the electrochemical cell is a state of charge (SoC) and the identified frequency shifts as a function of the SoC.

3. The method according to claim 2, wherein:
a frequency shift of the identified frequency as a function of the SoC is reversible.

4. The method according to claim 1, wherein:
the state of the electrochemical cell is a state of health (SoH) and the identified frequency shifts as a function of the SoH.

5. The method according to claim 4, wherein:
a frequency shift of the identified frequency as a function of the SoH is irreversible.

6. The method according to claim 1, further comprising:
correlating an amplitude of the at least one resonance peak to the state of the electrochemical cell.

7. The method according to claim 1, wherein:
the single frequency acoustic wave is generated by applying a continuous-wave electrical excitation signal across two electrodes of the piezoelectric element, and
the sweeping of the single frequency is provided by sweeping a frequency of the continuous-wave electrical excitation signal.

8. The method according to claim 7, wherein:
the frequency-dependent electrical response is an electrical impedance of the piezoelectric element measured across the two electrodes.

9. The method according to claim 1, further comprising:
acoustically coupling an additional piezoelectric element to the electrochemical cell;
applying a continuous-wave electrical excitation signal across two electrodes of the additional piezoelectric element, thereby coupling the single frequency acoustic wave to the electrochemical cell; and
sweeping a frequency of the continuous-wave electrical excitation signal, thereby sweeping the single frequency of the acoustic wave over the predetermined frequency range.

10. The method according to claim 9, wherein:
the frequency-dependent electrical response is a voltage ratio of a voltage of an electrical signal measured across two electrodes of the piezoelectric element and a voltage of the continuous-wave electrical excitation signal.

11. The method according to claim 9, wherein:
the piezoelectric element and the additional piezoelectric element are acoustically coupled at opposite surfaces of the electrochemical cell to provide a propagation path of the acoustic wave through a thickness of the electrochemical cell.

12. A system for determining a state of an electrochemical cell, the system comprising:
an electrochemical cell;
a piezoelectric element acoustically coupled to the electrochemical cell; and
a control circuit configured to:
generate a continuous-wave electrical excitation signal over a predetermined frequency range, the excitation signal used to generate a single frequency acoustic wave that is coupled to the electrochemical cell,
measure a frequency-dependent electrical response of the piezoelectric element over the predetermined frequency range to generate a frequency spectrum;
identify a frequency of at least one resonance peak within the generated frequency spectrum, the at least one resonance peak corresponding to a resonant mode of the electrochemical cell; and
determine the state of the electrochemical cell based on the identified frequency of the at least one resonance peak.

13. The system according to claim 12, wherein:
the state of the electrochemical cell is a state of charge (SoC) and the identified frequency shifts as a function of the SoC.

14. The system according to claim 13, wherein:
a frequency shift of the identified frequency as a function of the SoC is reversible.

15. The system according to claim 12, wherein:
the state of the electrochemical cell is a state of health (SoH) and the identified frequency shifts as a function of the SoH.

16. The system according to claim 15, wherein:
a frequency shift of the identified frequency as a function of the SoH is irreversible.

17. The system according to claim 12, wherein:
the control circuit is further configured to determine the state of electrochemical cell based on an amplitude of the at least one resonance peak.

18. The system according to claim 12, wherein:
the single frequency acoustic wave is generated by applying the continuous-wave electrical excitation signal across two electrodes of the piezoelectric element.

19. The system according to claim 18, wherein:
the frequency-dependent electrical response is an electrical impedance of the piezoelectric element measured across the two electrodes.

20. The system according to claim 12, wherein:
the system further comprises an additional piezoelectric element acoustically coupled to the electrochemical cell,
the continuous-wave electrical excitation signal is applied across two electrodes of the additional piezoelectric element to generate the single frequency acoustic wave that is coupled to the electrochemical cell.

21. The system according to claim 20, wherein:
the frequency-dependent electrical response is a voltage ratio of a voltage of an electrical signal measured across two electrodes of the piezoelectric element and a voltage of the continuous-wave electrical excitation signal.

22. The system according to claim 20, wherein:
the piezoelectric element and the additional piezoelectric element are acoustically coupled at opposite surfaces of the electrochemical cell to provide a propagation path of the acoustic wave through a thickness of the electrochemical cell.
